(19) United States
(12) Patent Application Publication
(10) Pub. No.: US 2024/0204011 A1
(43) Pub. Date: Jun. 20, 2024

(54) SEMICONDUCTOR DEVICE, SENSOR DEVICE, AND ELECTRONIC DEVICE

(71) Applicant: WUHAN CHINA STAR OPTOELECTRONICS TECHNOLOGY CO., LTD., Wuhan, Hubei (CN)

(72) Inventors: Zhifu Li; Guanghui Liu; Guowei Zha; Zhou Zhang; Xialing Liu

(73) Assignee: WUHAN CHINA STAR OPTOELECTRONICS TECHNOLOGY CO., LTD., Wuhan, Hubei (CN)

(21) Appl. No.: 17/905,176

(22) PCT Filed: Aug. 17, 2022
(86) PCT No.: PCT/CN2022/113026

§ 371 Date: Aug. 28, 2022

(30) Foreign Application Priority Data
Aug. 1, 2022 (CN) 202210913726.9

(51) Int. Cl. H01L 27/12

(52) U.S. Cl. CPC H01L 27/1251; H01L 27/1225; H01L 27/124

(57) ABSTRACT

A semiconductor device, a sensor device, and an electronic device are provided. The semiconductor device includes a first integrated circuit (IC) and a second IC which are disposed on an insulating substrate. The first IC includes a first thin-film transistor (TFT). The second IC includes a second TFT. Mobility of the first TFT is greater than mobility of the second TFT. The ICs are disposed on the insulating substrate, thereby reducing manufacturing cost.

### FIELD

The present disclosure relates to a field of manufacturing display panels, and more particularly, to a semiconductor device, a sensor device, and an electronic device.

### BACKGROUND

With continuous development of semiconductor manufacturing technologies, computer integrated control systems have been increasingly applied to many fields. For example, diverse machines, such as intelligent vehicles, are provided with a semiconductor device to control such devices.

In conventional technologies, during processes of manufacturing semiconductors, the semiconductor devices are usually manufactured on a silicon substrate, thereby forming a silicon substrate chip which is a circuit component constituted by a semiconductor film, a conductive film, and an insulating film stacked on a silicon substrate. By integrating multiple components on a silicon substrate, a semiconductor device having a small size, a light weight, and integration can be realized. However, compared to other manufacturing material, monocrystalline silicon substrates used to form a carrier have high manufacturing cost, high integration degrees, and complicated manufacturing processes. Furthermore, demand for semiconductor devices grows increasingly, and silicon substrate material having high cost will limit supply of semiconductor devices, which is not beneficial for controlling manufacturing cost and developing a semiconductor industry. Therefore, it is necessary to find alternative material and manufacturing processes of devices to reduce manufacturing cost and improve comprehensive performance of the devices.

As such, it is necessary to provide a solution to solve conventional issues.

Regarding the technical issues:

In conventional manufacturing processes of semiconductor devices, the semiconductor devices have high manufacturing cost and complicated manufacturing processes, which is not beneficial for a large supply of semiconductor devices and development of a semiconductor industry.

### SUMMARY

To solve the above issues, embodiments of the present disclosure provide a semiconductor device, a sensor device, and an electronic device to effectively improve manufacturing processes, reduce manufacturing cost, and enhance comprehensive performance of devices.

To solve the above technical issues, the present disclosure provides a semiconductor device, comprising:
a first integrated circuit (IC) disposed on the insulating substrate and comprising a first thin-film transistor (TFT); and
a second IC disposed on the insulating substrate and comprising a second TFT;
wherein mobility of a charge carrier in an active layer of the first TFT is greater than mobility of a charge carrier in an active layer of the second TFT.

According to one embodiment of the present disclosure, along a length direction of a channel area corresponding to the first TFT and the second TFT, an average size of a plurality of particles in the active layer of the first TFT is greater than an average size of a plurality of particles in the active layer of the second TFT.

According to one embodiment of the present disclosure, the particles in the active layer of the first TFT comprise a first boundary along the first direction and a second boundary along the second direction; and
wherein the first direction is same as the length direction of the channel area, the second direction is perpendicular to the length direction of the channel area, and a length of the first boundary is greater than a length of the second boundary.

According to one embodiment of the present disclosure, the active layer of the first TFT and the active layer of the second TFT have same material, the active layer of the first TFT and the active layer of the second TFT are disposed on a same layer, a gate of the first TFT and a gate of the second TFT are disposed on a same layer, and a source/drain metal layer of the first TFT and a source/drain metal layer of the second TFT are disposed on a same layer.

According to one embodiment of the present disclosure, a gate of the first TFT is insulatedly disposed on the active layer of the first TFT, a source/drain metal layer of the first TFT is insulatedly disposed on the gate of the first TFT, the active layer of the second TFT is insulatedly disposed on the source/drain metal layer of the first TFT, and a gate of the second TFT is insulatedly disposed on the active layer of the second TFT.

According to one embodiment of the present disclosure, the first TFT comprises a low-temperature polycrystalline silicon TFT, and the second TFT comprises a metal oxide TFT;
wherein the active layer of the first TFT is disposed on the insulating substrate, a gate of the first TFT is insulatedly disposed on the active layer of the first TFT, and a gate of the second TFT and the gate of the first TFT are disposed on a same layer.

According to one embodiment of the present disclosure, the semiconductor device comprises a gate insulating layer disposed on the gate of the first TFT and the gate of the second TFT, wherein the active layer of the second TFT is disposed on the gate insulating layer, the source/drain metal layer of the first TFT and the source/drain metal layer of the second TFT are disposed on a same layer and are disposed on the gate insulating layer.

According to one embodiment of the present disclosure, the source/drain metal layer of the second TFT is at least partly disposed on a surface of the active layer of the second TFT, and is electrically connected to the active layer of the second TFT.

According to one embodiment of the present disclosure, a type of the first TFT and a type of the second TFT are different, the second TFT is disposed on the first TFT, and the semiconductor device comprises a passivation layer disposed between the first TFT and the second TFT.

According to one embodiment of the present disclosure, the semiconductor device comprises a second gate insulating layer, a gate of the second TFT is disposed on the passivation layer, the second gate insulating layer is disposed on the passivation layer, the active layer of the second TFT is disposed on the second gate insulating layer, and the source/drain metal layer of the second TFT is disposed on the second gate insulating layer; and

wherein the source/drain metal layer of the second TFT is at least partly disposed on a surface of the active layer of the second TFT, and is electrically connected to the active layer of the second TFT.

According to one embodiment of the present disclosure, the first IC comprises any one of a gate driving IC, a logic control IC, a low-pass control IC, or a digital-to-analog converter IC, and the second IC comprises any one of a memory IC or an operational amplifier IC.

According to a second aspect of an embodiment of the present disclosure, the present disclosure further provides a sensor device, comprising a sensor area and an outer circuit area defined on a side of the sensor area;
wherein the sensor device comprises:
an insulating substrate;
a sensor unit disposed on the insulating substrate corresponding to the sensor area; and
an integrated circuit (IC), wherein the IC is at least partly disposed on the insulating substrate corresponding to the outer circuit area, and is configured to control the sensor unit;
wherein the IC comprises:
a first IC disposed on the insulating substrate and comprising a first thin-film transistor (TFT); and
a second IC disposed on the insulating substrate and comprising a second TFT;
wherein mobility of a charge carrier in an active layer of the first TFT is greater than mobility of a charge carrier in an active layer of the second TFT.

According to one embodiment of the present disclosure, in the sensor area, the sensor device comprises:
a plurality of gate signal lines; and
a plurality of data signal lines, wherein the data signal lines and the gate signal lines cross each other and form a plurality of intersection areas, each of the intersection areas is provided with at least one sensor unit, and the sensor unit comprises a first sensor module;
wherein the data signal lines are electrically connected to the first sensor module, and the data signal lines are electrically connected to an IC disposed in the outer circuit area.

According to one embodiment of the present disclosure, the data signal lines are electrically connected to the first IC, the second IC is electrically connected to the first IC, and the first IC is electrically connected between the sensor unit and the second IC.

According to one embodiment of the present disclosure, the first IC comprises any one of a low-pass control IC, the analog control IC, or a digital-to-analog converter IC, and the second IC comprises any one of a memory IC or an operational amplifier IC.

According to one embodiment of the present disclosure, the first IC comprises a low-pass control IC electrically connected to the data signal line, an analog control IC electrically connected to the low-pass control IC, and a digital-to-analog converter IC electrically connected to the analog control IC, the second IC comprises a memory IC, the low-pass control IC is electrically connected between the sensor unit and the analog control IC, and the digital-to-analog converter IC is electrically connected between the analog control IC and the memory IC.

According to one embodiment of the present disclosure, active layer of the first TFT comprises low-temperature polycrystalline silicon, and the active layer of the second TFT comprises a metal oxide.

According to one embodiment of the present disclosure, the first IC and the second IC are both disposed on a same side of the insulating substrate, the first sensor module is disposed on a side of the first IC away from the insulating substrate, and the first sensor module is electrically connected to the first TFT.

According to one embodiment of the present disclosure, the first IC and the second IC are both disposed on a first surface of the insulating substrate, and the first sensor module is disposed on a second surface of the insulating substrate opposite to the first surface; and
wherein the first sensor module is electrically connected to the first TFT by a through-hole define on the insulating substrate.

According to a third aspect of an embodiment of the present disclosure, the present disclosure provides an electronic device, comprising a semiconductor device;
wherein the semiconductor device comprises the semiconductor device or the sensor device provided by the embodiments of the present disclosure.

Regarding the beneficial effects:
in summary, beneficial effects of embodiments of the present disclosure are:

Embodiments of the present disclosure provide a semiconductor device, a sensor device, and an electronic device. The semiconductor device comprises a first integrated circuit (IC) and a second IC. The first IC comprises a first thin-film transistor (TFT) and a second TFT disposed on an insulating substrate. Mobility of a charge carrier in an active layer of the first TFT is greater than mobility of a charge carrier in an active layer of the second TFT. In the embodiments of the present disclosure, a TFT device of an IC is directly disposed on the insulating substrate, and different TFT devices have different mobilities. High-cost semiconductor material is replaced by low-cost insulating material, thereby reducing manufacturing cost and improving performance of devices.

### DESCRIPTION OF DRAWINGS

FIG. 1A is a simplified schematic view showing an IC provided by an embodiment of the present disclosure.

FIG. 1B is a structural schematic view showing layers corresponding to the IC provided by the embodiment of the present disclosure.

FIG. 2 is a structural schematic view showing a sensor device provided by an embodiment of the present disclosure.

FIG. 3 is a structural schematic view showing layers of a semiconductor device provided by an embodiment of the present disclosure.

FIG. 4 is a structural schematic view showing layers of another semiconductor device provided by an embodiment of the present disclosure.

FIG. 5 is a plan schematic layout diagram showing an IC corresponding to an insulating substrate provided by an embodiment of the present disclosure.

FIGS. 6 to 9 are structural schematic views showing arrangements of different ICs provided by an embodiment of the present disclosure.

FIGS. 10 to 13 are structural schematic views showing of layer arrangements of different semiconductor devices provided by an embodiment of the present disclosure.

FIG. 14 is a structural schematic view showing an inner crystal of an active layer provided by an embodiment of the present disclosure.

FIG. 15 is a structural schematic view showing layers of another semiconductor device provided by an embodiment of the present disclosure.

FIG. 16 is a structural schematic view showing layers of yet another semiconductor device provided by an embodiment of the present disclosure.

### DETAILED DESCRIPTION

The following description of the various embodiments is provided with reference to the accompanying drawings to demonstrate the embodiments of the present disclosure.

With the continuous improvement of digitalization and intelligence, semiconductor devices require more and more ICs. The ICs can effectively control the devices and improve performance of the devices. However, during processes of manufacturing ICs, electronic components are usually integrated on silicon wafer substrates which have high cost. Furthermore, the manufacturing processes are complicated, which is not beneficial for further improving IC technologies.

An embodiment of the present disclosure provides a semiconductor device to effectively processes of manufacturing ICs and effectively reduce manufacturing cost of the ICs.

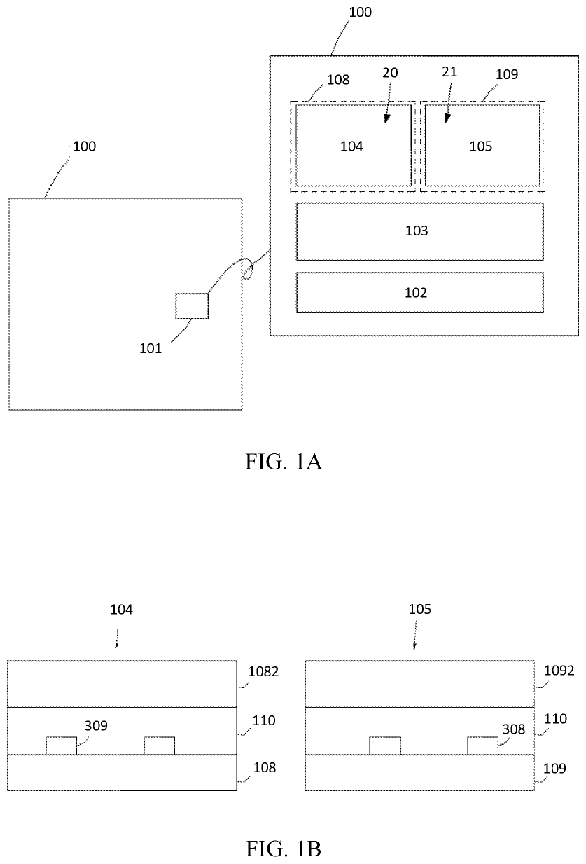

As shown in FIG. 1A, a simplified schematic view showing an IC provided by an embodiment of the present disclosure is provided. In following embodiments, a control IC of a vehicle control system is taken as an example. The IC may further be applied to other control devices which are not described here. Specifically, the vehicle control device may be a touch control display panel device. A plurality of control devices are disposed in the touch control display panel, and each of the control devices is provided with the IC. Moreover, a plurality of touch control units or a plurality of touch control modules are integrated on the IC.

Specifically, in the present embodiments, the touch control display panel includes a support circuit board 100. Furthermore, a plurality of chip integrating areas 101 are defined in the support circuit board 100, and each of the chip integrating areas 101 is provided with a corresponding IC.

Please refer to a partly enlarged schematic view of FIG. 1A for details. In the present embodiment, each of the chip integrating areas 101 is provided with a plurality of ICs, e.g., a first IC 104 and a second IC 105. The first IC 104 and the second IC 105 are disposed on the support circuit board 100 and are mechanically or electrically connected to each other. When the first IC 104 and the second IC 105 need to work together, the first IC 104 and the second IC 105 are electrically connected to each other. When the first IC 104 and the second IC 105 work individually, the first IC and the second IC 105 may be mechanically and insulatedly connected to each other.

In the present embodiment, the first IC 104 and the second IC 105 may have a same function or different functions. For example, the first IC 104 is a digital control IC, and the second IC 105 is a signal control IC. A touch control display panel can be controlled and operated by the first IC 104 and the second IC 105.

Furthermore, in the first IC 104 and the second IC 105, the first IC 104 includes a first base layer 108, and the second IC 105 includes a second base layer 109. That is, a substrate used to manufacture the first IC 104 is the first base layer 108, and a substrate used to manufacture the second IC 105 is the second base layer 109.

In the present embodiment, the first base layer 108 and the second base layer 109 are insulating substrates. Preferably, the first base layer 108 and the second base layer 109 are glass substrates. By replacing conventional silicon substrates, which an IC is disposed on, with glass substrates provided by the present embodiment, manufacturing cost of the IC can be effectively reduced, and an arrangement area of the IC can be optimized.

In the present embodiment, a third IC 102 and a fourth IC 103 are further disposed in each of the chip integrating areas 101. The third IC 102 and the fourth IC 103, and the first IC 104 and the second IC 105 are disposed on different positions. For example, the third IC 102 and the fourth IC 103 are disposed in different rows of the first IC 104. The third IC 102 and the fourth IC 103 may have different functions, which can be determined according to requirements for controlling actual products.

Furthermore, each of the above ICs may include a memory IC, a logic control IC, an analog control IC, a low-pass control IC, or a digital-to-analog converter IC. Arrangements of ICs are determined according to the ICs' functions. For example, ICs having high performance, such as logic control ICs, low-pass control ICs, sensor ICs, and digital-to-analog converter ICs, are provided with corresponding TFTs having high mobility. ICs having low performance, such as memory ICs, are provided with corresponding TFTs having low mobility. Therefore, devices are ensured to work normally.

Please refer to FIG. 1B for details. FIG. 1B is a structural schematic view showing layers corresponding to the IC provided by the embodiment of the present disclosure. In the present embodiment, the first IC 104 includes the first base layer 108, a dielectric layer 110, and a first TFT 309 disposed in the dielectric layer 110. The first TFT 309 is disposed on the first base layer 108. The dielectric layer 110 is disposed on the first base layer 108 and covers a corresponding TFT. The second IC 105 includes the second base layer 109, the dielectric layer 110, and a second TFT 308 disposed in the dielectric layer 110.

In the present embodiment, when the TFT disposed in the dielectric layer 110 is manufactured, each of the ICs can be provided with multiple same or different TFTs.

In following embodiments, the first IC includes multiple first TFTs 309, and the second IC includes multiple second TFTs 308. The TFTs may be individually disposed on the corresponding insulating substrate in an array manner.

Furthermore, mobility of a charge carrier in an active layer of the first TFT 309 is greater than mobility of a charge carrier in an active layer of the second TFT 308.

In the present embodiment, the first TFT and the second TFT may be disposed on a same layer, or may be stacked. A length of a channel area of the active layer of the first TFT may be greater than a length of a channel area of the active layer of the second TFT, thereby fitting devices having different sizes. This can be determined according to performance and specification of corresponding ICs, which is not described here.

Preferably, particles are formed in an active layer of different TFTs. For example, particles are formed in a channel area of an active layer. In the present embodiment, since mobility of the first TFT is greater than mobility of the second TFT, an average size of particles in the channel area of the first TFT is greater than an average size of particles in the channel area of the second TFT.

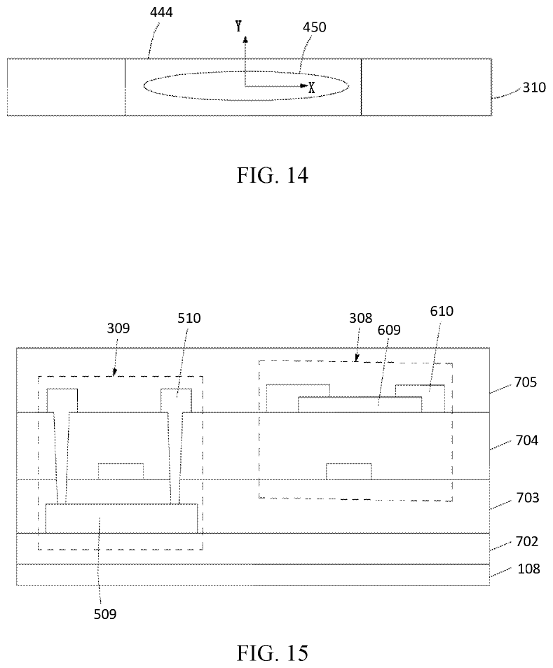

Preferably, as shown in FIG. 14, a structural schematic view showing particles in an active layer provided by the present embodiment is provided. A channel area 444 of a first active layer 310 of the first TFT includes a first particle 450. The first particle 450 includes a first direction X and a second direction Y. The first direction X and an extension direction of the channel area 444 are same. For example, the first direction X is parallel to a long length of the first active layer, and the second direction Y is a vertical direction and is perpendicular to the channel area. In the present embodiment, the first particle 450 has a first boundary along the first direction X and a second boundary along the second direction Y. A length of the first boundary is greater than a length of the second boundary. Therefore, a charge carrier can move in an entire particle as much as possible, and mobility of the charge carrier can be increased.

Furthermore, please refer to FIG. 1B for details. The IC further includes a first wiring layer 1082 and a second wiring layer 1092. The first wiring layer 1082 is disposed on the first TFT 309, and the second wiring layer 1092 is disposed on the second TFT 308. Each of the wiring layers can be electrically connected to a corresponding TFT by a corresponding metal line, thereby eventually forming the IC provided by the present embodiment.

In the present embodiment, the first IC and the second IC may also be stacked. Meanwhile, the first IC can be bonded to the second IC.

Specifically, in the present embodiment, when the first IC 104 or the second IC 105 is manufactured, a TFT is formed on the first base layer 108 or the second base layer 109, then other wiring layers are formed on the TFT, and finally each of the ICs is encapsulated.

Specifically, please refer to FIG. 1A for details. The first base layer 108 is disposed on a corresponding position of a first area 20, and the second base layer 109 is disposed on a corresponding position of a second area 21. The first area 20 may be defined on a side of the second area 21. The first base layer 108 disposed in the first area 20 and the second base layer 109 disposed in the second area 21 may have a same size.

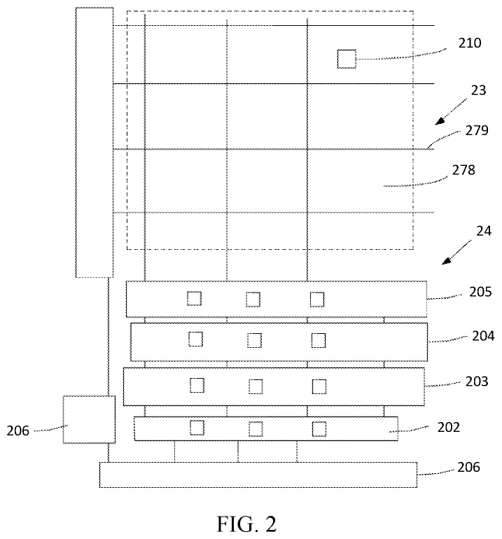

Please refer to FIG. 2 for details, a structural schematic view showing a sensor device provided by an embodiment of the present disclosure is provided. The semiconductor device is provided with multiple ICs provided by an embodiment of the present disclosure. In the present embodiment, the semiconductor device is the sensor device which is taken as an example.

Specifically, the sensor device includes a sensor area 23 and an outer circuit area 24 defined on a side of the sensor area 23. The sensor area 23 includes a plurality of gate signal lines 279 and a plurality of data signal lines 278. The gate signal lines 279 cross the data signal lines 278, thereby forming a plurality of intersection areas. Moreover, each of the intersection areas is provided with at least one sensor unit. In the present embodiment, the sensor unit is a first sensor module 210 which is taken as an example. The data signal lines 278 are electrically connected to the sensor module 210, and the data signal lines are electrically connected to an IC disposed in the outer circuit area 24, thereby controlling the first sensor module 210 by the IC. In the present embodiment, the semiconductor device may also be other devices which are not described here.

In the present embodiment, the outer circuit area is provided with different ICs. The ICs, such as the first IC and the second IC, are disposed on the insulating substrate. Specifically, the data signal lines 278 are electrically connected to the first IC, the second IC is electrically connected to the first IC, and the first IC is electrically connected between the first sensor module 210 and the second IC.

Different ICs can realize different control functions. In the present embodiment, the first IC may include a plurality of logic control ICs 206, a plurality of low-pass control ICs 205, a plurality of digital-to-analog converter ICs 203, and a plurality of analog control ICs 204. The second IC may include at least one of a memory IC 202 or an operation IC. Furthermore, the second IC is provided with a TFT having low mobility. A corresponding TFT disposed in the first IC is a low-temperature polycrystalline silicon TFT, and a corresponding TFT disposed in the second IC is a metal oxide TFT.

Specifically, the data signal lines 278 are electrically connected to the low-pass control ICs 205, the analog control ICs 204 are electrically connected to the low-pass control ICs 205, and the digital-to-analog converter ICs 203 are electrically connected to the analog control ICs 204. Furthermore, the low-pass control ICs 205 are electrically connected between the first sensor module 210 and the analog control ICs 204, and the digital-to-analog converter ICs 203 are electrically connected between the analog control ICs 204 and the memory ICs 202.

In the present embodiment, each of the above ICs can be manufactured by directly etching the insulating substrate. Each of the ICs is provided with a plurality of TFTs. Each of the TFTs of the ICs is manufactured according to the structure provided by the present embodiment which can effectively reduce manufacturing cost, improve manufacturing processes, and enhance working performance.

Furthermore, the sensor device is provided with a plurality of conductive wires which are arranged from the sensor area to the outer circuit area, thereby transmitting signals.

In the present embodiment, the sensor device further includes a voltage converter module and a shift register. Since the voltage converter module and the shift register need to have high performance, a plurality of TFTs of a plurality of ICs corresponding to the voltage converter module and the shift register may be low-temperature polycrystalline silicon TFTs which have high mobility. Details are not described here.

In the present embodiment, both the first IC and the second IC can be disposed on a same side of the insulating substrate. The first sensor module 240 is disposed on a side of the first IC away from the insulating substrate and is electrically connected to the first TFT of the first IC.

Furthermore, both the first IC and the second IC are disposed on a first surface of the insulating substrate, and the first sensor module is disposed on a second surface opposite to the first surface of the insulating substrate.

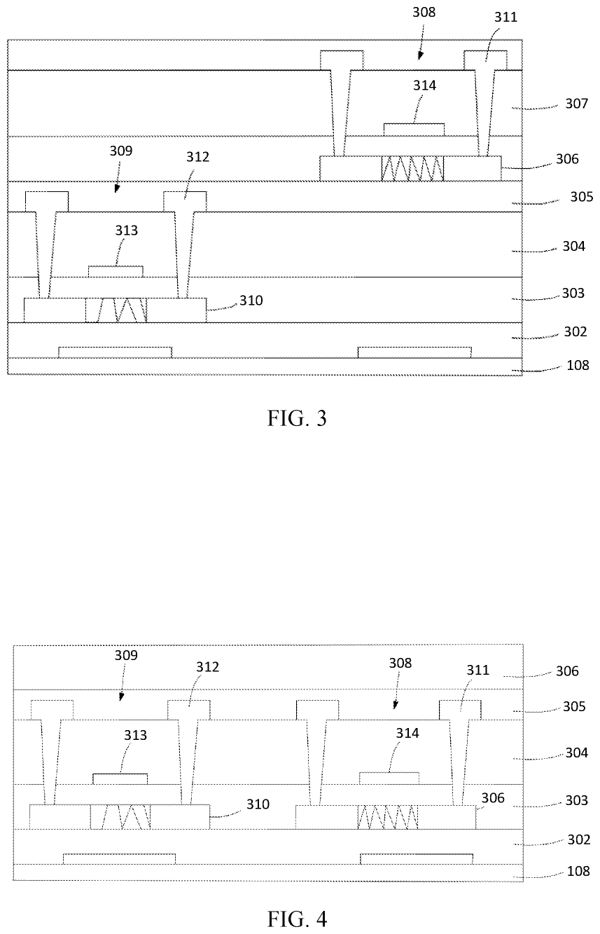

As shown in FIG. 3 for details, a structural schematic view showing layers of the semiconductor device provided by the present embodiment is provided. Specifically, the semiconductor device includes the first TFT 309 and the second TFT 308. The first TFT 309 is disposed on a side of the second TFT 308. The first TFT 309 and the second TFT 308 are stacked, thereby reducing an area of the IC.

The first base layer 108 is a glass layer. A light-shading layer is further disposed on the first base layer 108. A buffer layer 302 fully covers the light-shading layer. Furthermore, the first TFT 309 is further provided with a first active layer 310, a first gate insulating layer 303, a first gate 313, and a first interlayer dielectric layer 304.

In the present embodiment, the first active layer 310 is disposed on the first buffer layer 302, the first gate insulating layer 303 is disposed on the first buffer layer 302, and the first gate insulating layer 303 fully covers the first active layer 310. In addition, the first gate 313 is disposed on the first gate insulating layer 303, the first interlayer dielectric layer 304 is disposed on the first gate 313, and a first source/drain metal layer 312 is disposed on the first interlayer dielectric layer 304. The first source/drain metal layer 312 is electrically connected to the first active layer 310 by a corresponding through-hole.

Furthermore, a second buffer layer 305 is disposed on the first TFT 309. A second active layer 306 is disposed on the second buffer layer 305. A second gate 314 is disposed on the second active layer 306. A second interlayer dielectric layer 307 is disposed on the second active layer 306. A second source/drain metal layer 311 is disposed on the second interlayer dielectric layer 307. The second source/drain metal layer 311 is electrically connected to the second active layer 306 by a through-hole.

In the present embodiment, both the first TFT 309 and the second TFT can be low-temperature polycrystalline silicon TFTs, and mobility of a charge carrier in the first TFT 309 is greater than mobility of a charge carrier in the second TFT 308.

Specifically, an average size of particles of corresponding material of the channel area of the first active layer 310 is greater than an average size of particles of corresponding material of the channel area of the second active layer 306, thereby ensuring that mobility of the first TFT is greater than mobility of the second TFT. Therefore, ICs formed of different semiconductor devices have different functions, and ICs having different functions can have high performance when a high-speed signal or a low-speed signal is applied to the ICs. As such, working performance of the ICs can be improved.

In the present embodiment, in the first base layer, an orthographic projection of the first TFT 309 on the substrate does not fully overlap an orthographic projection of the second TFT 308 on the substrate.

Specifically, the semiconductor device is further provided with other components which can be electrically connected to a corresponding TFT, thereby transmitting signals. After encapsulation processes, the ICs having the insulating substrate are formed.

Furthermore, please refer to FIG. 3 and FIG. 4 together. FIG. 4 is a structural schematic view showing layers of another semiconductor device provided by the present embodiment is provided. In the present embodiment, when an IC corresponding to the semiconductor device is manufactured, the first TFT 309 and the second TFT 308 are disposed on a same layer.

Specifically, the first TFT 309 is disposed on a side of the second TFT 308, and the first active layer 310 of the first TFT 309 and the second active layer 306 of the second TFT 308 may be disposed on a same layer. Specifically, the first active layer 310 and the second active layer 306 both are disposed on the first buffer layer 302.

Moreover, the source/drain metal layer 312 of the first TFT 309 and the source/drain metal layer 311 of the second TFT 308 may be disposed on a same layer such as the first interlayer dielectric layer 304. In addition, the first gate 313 and the second gate 314 are disposed on a same layer. For example, the first gate 313 and the second gate 314 both are disposed on the first gate insulating layer 303.

In the present embodiment, the first TFT 309 may be electrically connected to the second TFT 308, thereby transmitting signals. In addition, the first TFT 309 and the second TFT 308 may be different TFTs having different functions. For example, mobility of a charge carrier in the first TFT 309 is greater than mobility of a charge carrier in the second TFT 308.

Specifically, the first TFT 309 and the second TFT 308 both are polycrystalline silicon TFTs.

Please refer to FIG. 15 for details, a structural schematic view showing layers of another semiconductor device provided by the present embodiment is provided. Specifically, the semiconductor device is provided with the first TFT 309 and the second TFT 308. An active layer 509 of the first TFT 309 is disposed on a buffer layer 702. In addition, a gate of the first TFT 309 and a gate of the second TFT 308 are both disposed on a gate insulating layer 703.

Furthermore, a source/drain metal layer 510 of the first TFT 309 and a source/drain metal layer 610 of the second TFT 308 are both disposed on a passivation layer 705. In the present embodiment, an active layer 609 of the second TFT 308 is disposed on the passivation layer 705. The source/drain metal layer of the second TFT 308 at least partly covers the active layer 609, and is electrically connected to the active layer 609. For example, the source/drain metal layer 610 of the second TFT is overlappingly connected to two edges of two sides of the active layer 609. Thus, a thickness of the second TFT 308 can be further reduced, thereby reducing a thickness of panels.

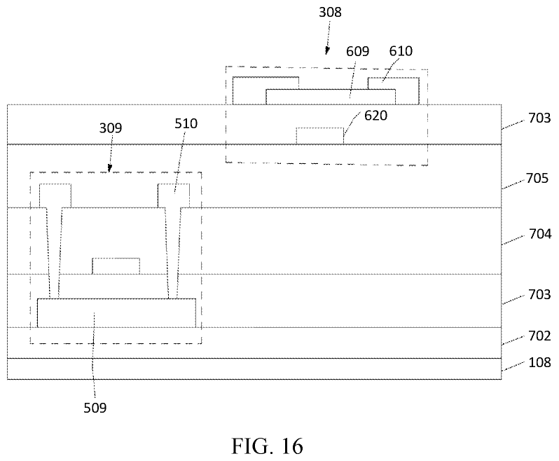

Furthermore, please refer to FIG. 15 and FIG. 16 together. FIG. 16 shows a structure of layers of yet another semiconductor device provided by an embodiment of the present disclosure. In the present embodiment, the first TFT 309 and the second TFT 308 are disposed on different layers. Specifically, the source/drain metal layer 510 of the first TFT 309 is disposed on an interlayer dielectric layer 704. The passivation layer 705 is disposed on the interlayer dielectric layer 704. The passivation layer 705 covers the source/drain metal layer 510.

Moreover, a gate 620 of the second TFT 308 is disposed on the passivation layer 705. A gate insulating layer 703 is disposed on the passivation layer 705 and fully covers the gate 620. In addition, the active layer 609 is disposed on the gate insulating layer 703, and the source/drain metal layer 610 of the second TFT 308 is disposed on the gate insulating layer 703. In the present embodiment, the source/drain metal layer of the second TFT 308 at least partly covers the active layer 609 and is electrically connected to the active layer 609. For example, the source/drain metal layer 610 of the second TFT is overlappingly connected to two edges of two sides of the active layer 609, thereby making the first TFT 309 and the second TFT 308 form a stacked structure. In FIG. 15 and FIG. 16, the first TFT 309 may be a low-temperature polycrystalline silicon TFT, and the second TFT may be a metal oxide TFT.

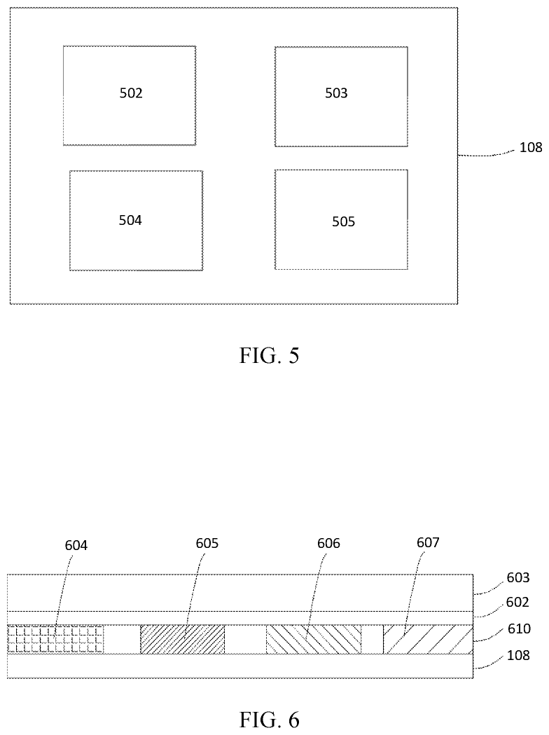

Please refer to FIG. 5 for details. FIG. 5 is a plan schematic layout diagram showing an IC corresponding to an insulating substrate provided by an embodiment of the present disclosure. In an IC, a plurality of different TFTs are disposed in different areas of a base layer. Specifically, an oxide TFT is disposed in an area 502. The oxide TFT is manufactured by processes of manufacturing the oxide TFT. A low-temperature polycrystalline silicon TFT is disposed in an area 503, or an amorphous silicon TFT is disposed in an area 504. In addition, a metal oxide TFT is disposed in an area 505.

Please refer to the structural schematic view of FIG. 2 together. In the present embodiment, when different ICs are disposed, the ICs may be disposed on a same side of the insulating substrate or on two sides of the insulating substrate. Also, the ICs may be stacked. Thus, an interior structure of devices can be further improved.

The above different TFTs can be chosen according to a function of a memory IC. For example, if a corresponding IC needs a low leakage current, a metal oxide TFT can be chosen. If a corresponding IC needs a high push force, a low-temperature polycrystalline silicon TFT can be chosen. Encapsulation processes are conducted sequentially. Thus, working performance of manufactured ICs can be effectively improved.

Furthermore, please refer to FIGS. 2 and 6 to 9. FIGS. 6 to 9 are structural schematic views showing arrangements of different ICs provided by an embodiment of the present disclosure. In the present embodiment, a sensor device is taken as an example. The sensor device includes a plurality of ICs having different functions. For example, the sensor device can be constituted by a memory IC, a digital-to-analog IC, a power driver IC, and a low-pass control IC cooperated with a first sensor module.

Please refer to FIG. 6 for details. Different areas of a first base layer 108 correspond to different ICs such as a first IC 605, a second IC 604, a third IC 603, a fourth IC 607, and a sensor unit 603. Specifically, the second IC 604 is a memory IC. The first IC 605 is a digital-to-analog IC. The third IC 606 is a power driver IC. The third IC 607 is a low-pass control IC. Preferably, the above ICs may further be replaced by ICs having other functions which are not described here. Furthermore, the sensor unit 603 is a photosensor unit.

In the present embodiment, the second IC 604, the first IC 605, the third IC 606, and the fourth IC 607 are disposed on the first base layer 108 and are disposed on a same side of the base layer 108.

In the present embodiment, a plurality of TFTs disposed in the ICs may be stacked. Specifically, the sensor unit 603 is disposed on the buffer layer 602, and the buffer layer 602 is disposed on another IC. Therefore, the sensor unit 603 and other ICs form a stacked structure.

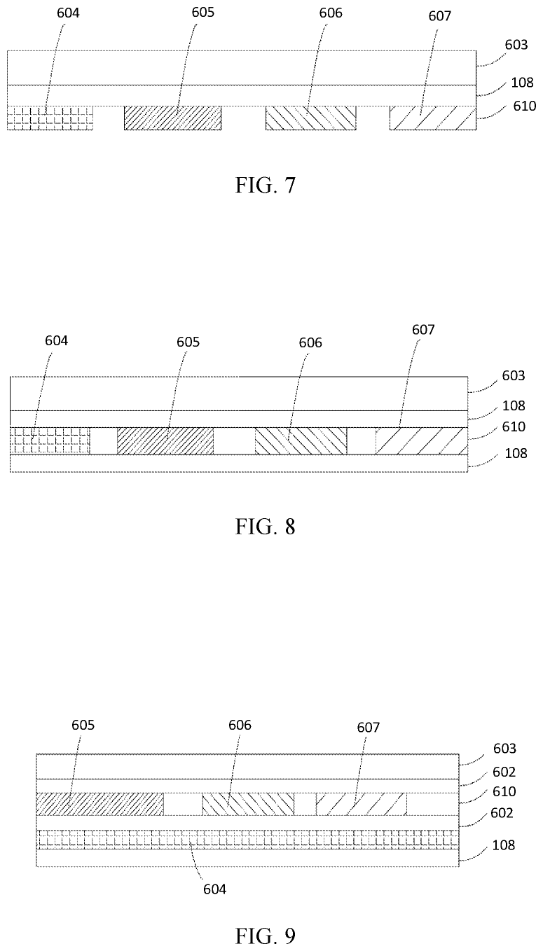

Please refer to FIG. 6 and FIG. 7 together. In the present embodiment, different ICs are disposed on two sides of the first base layer 108. That is, the sensor unit 603 and TFTs corresponding to other ICs are respectively disposed on two sides of the first base layer 108. For example, the sensor unit 603 is disposed on a surface of the first base layer, and the second IC 604, the first IC 605, the third IC 606, and the fourth IC 607 are disposed on a back surface of the first base layer. Thus, different ICs are disposed on a first surface and a second surface opposite to the first surface of the first base layer. Thus, a structure of the ICs is improved, and working performance is enhanced.

Please refer to FIG. 8 for details. In the present embodiment, the first base layer 108 includes two layers which are stacked. For example, the second IC 604, the first IC 605, the third IC 606, and the fourth IC 607 are disposed on a same base layer. Meanwhile, the sensor unit 603 is disposed on another base layer and is disposed on another IC. Therefore, a multilayer structure is formed. The sensor unit 603 can be bonded by a corresponding through-hole. Alternatively, the sensor unit 603 can be bonded to a lateral surface to be connected to another IC.

Please refer to FIG. 9. In the present embodiment, the sensor unit and other ICs are stacked and are disposed on a same first base layer 108.

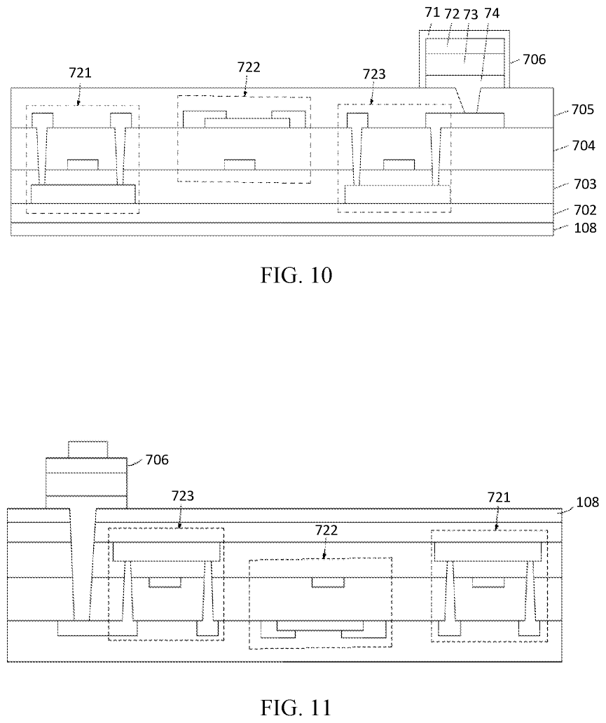

Furthermore, as shown in FIGS. 10 to 13, structural schematic views showing layers corresponding to arrangements of different semiconductor devices are provided. Layer structures as shown in FIGS. 10 to 13 respectively correspond to layer arrangements of layers as shown in FIGS. 6 to 9.

Specifically, as shown in FIG. 10 for details, the semiconductor device includes the first base layer 108, a plurality of TFTs disposed on the first base layer 108 in an array manner, and a plurality of dielectric layers. Specifically, the dielectric layers include the buffer layer 702, the gate insulating layer 703, the interlayer dielectric layer 704, and the passivation layer 705.

The buffer layer 702 is disposed on the first base layer 108, and the gate insulating layer 703 is disposed on the buffer layer 702. The interlayer dielectric layer 704 is disposed on the gate insulating layer 703, and the passivation layer 705 is disposed on the interlayer dielectric layer 704. In the present embodiment, the first base layer 108 is an insulating substrate.

A plurality of TFTs are disposed in the semiconductor device and may correspond to different ICs. For example, the first IC includes a first TFT 721, the second IC includes a second TFT 722, and the third IC includes a third TFT 723. Each of the TFTs includes an active layer, a gate, and a source/drain metal layer. Specific structures are as shown in the drawings and are not described here.

In the present embodiment, the semiconductor device further includes a first sensor module 706. The first sensor module 706 is a sensor unit such as a photosensor unit. The first sensor module 706 is disposed on the passivation layer 705 and is electrically connected to the third TFT 723.

In the present embodiment, the first sensor module 706 includes a first sensor electrode 72, a second sensor electrode 73, a connector electrode layer 74, and an enhancement layer 71. Specifically, the first sensor electrode 72, the second sensor electrode 73, and the connector electrode layer 74 are stacked. The connector electrode layer 72 is disposed on the passivation layer 705 and is electrically connected to the source/drain metal layer of the third TFT 723 by a through-hole.

Furthermore, the enhancement layer 71 surrounds and covers the first sensor electrode, the second sensor electrode, and the connector electrode layer. When external light enters layers, the enhancement layer will receive the light, thereby improving a light-sensing effect.

Furthermore, the above TFTs may be different. In following embodiments, the first TFT 721 and the third TFT 723 both are low-temperature polycrystalline silicon TFTs, the second TFT is a metal oxide TFT such as an indium gallium zinc oxide (IGZO) TFT.

Please refer to FIG. 10 for details. Mobility of the active layer of the first TFT 721 is greater than mobility of the active layer of the second TFT 722. By disposing different TFTs in ICs, performance of the ICs can be improved.

In FIG. 10, the TFTs are disposed on a same layer and are disposed on a same side of the insulating substrate. Specifically, the active layer of the first TFT 721 and an active layer of the third TFT are disposed on a same layer and are disposed on the buffer layer 702. Meanwhile, a gate of the first TFT 721 is disposed between the active layer and the source/drain metal layer, thereby forming a top-gate structure. In the second TFT 722, a gate is disposed on a corresponding layer below the active layer, thereby forming a bottom-gate structure.

In the present embodiment, the source/drain metal layer of the first TFT 721 and the source/drain metal layer of the second TFT 722 are disposed on a same layer. For example, the source/drain metal layer of the first TFT 721 and the source/drain metal layer of the second TFT 722 are disposed on the interlayer dielectric layer 704. Furthermore, the gate of the first TFT 721 and the gate of the second TFT 722 are disposed on a same layer. For example, the gate of the first TFT 721 and the gate of the second TFT 722 are disposed on the gate insulating layer 703. The source/drain metal layer of the second TFT 722 is at least partly disposed on a surface of the active layer of the second TFT. Thus, corresponding ICs of the above TFTs are disposed on a same side of the insulating substrate. In addition, the first sensor module 706 is disposed on the third TFT 723 and is disposed on a same side as the ICs.

In FIG. 11, the first sensor module 706 and the TFTs are disposed on two sides of the base layer 108, thereby forming a double-surface structure.

Specifically, the first TFT 721, the second TFT 722, and the third TFT 723 are disposed on a same side of the first base layer, and the first sensor module 706 is disposed on another side of the first base layer 108. The first sensor module 706 is electrically connected to the third TFT 723 by a through-hole structure. For example, the first sensor module 706 is electrically connected to a drain of the third TFT 723.

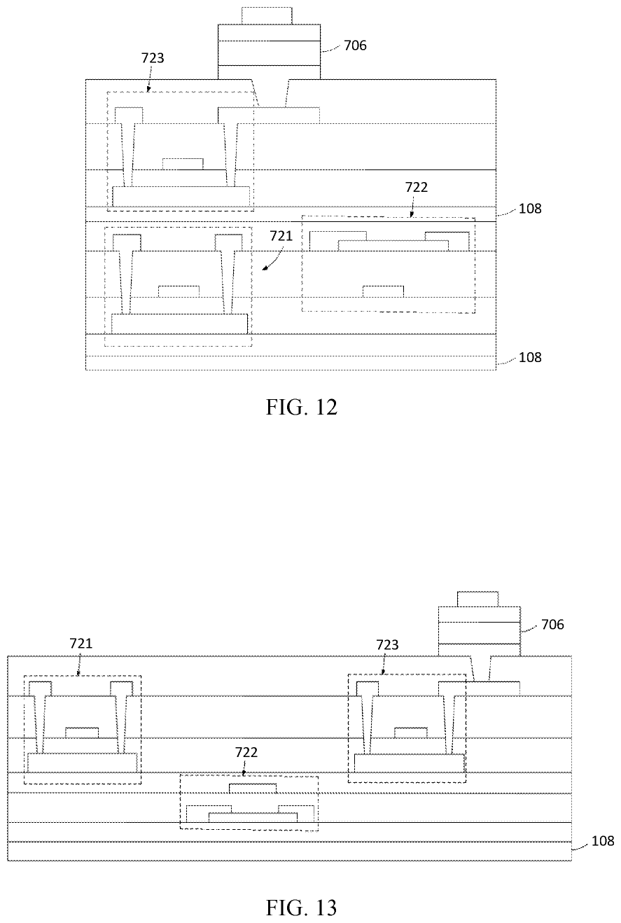

Please refer to FIG. 12 for details. In the present embodiment, the TFTs disposed in a photosensor IC have a stacked structure. The first TFT 721 and the second TFT 722 are disposed on a same first base layer 108, and the third TFT 723 corresponding to the first sensor module 706 is disposed on another first base layer 108. Two first base layers 108 are stacked. As such, an area of the ICs can be further reduced, and performance of the ICs can be improved.

Furthermore, as shown in FIG. 13 which also shows a stacked structure. Specifically, the first TFT 721 and the third TFT 723 corresponding to the first sensor module 706 are disposed on a same layer, and the second TFT 722 is disposed on a layer below the layer where the first TFT 721 and the third TFT 723 corresponding to the first sensor module 706 are disposed. Specifically, the active layer of the first TFT 721 and the active layer of the third TFT 723 are disposed on the gate insulating layer. The gate insulating layer is disposed on the gate of the second TFT and fully covers the gate of the second TFT. Finally, an IC with the first sensor module 706 is formed.

In the present embodiment, when the first base layer includes the above stacked layer or a flat structure, connection of corresponding signal lines can be realized by a metal line and a through hole. A lateral-side bonding process or a bottom-side bonding process can be applied to connecting processes. Then, the connecting line and the first base layer are encapsulated to finally form the ICs provided by the present embodiment.

An embodiment of the present disclosure further provides an electronic device, including the semiconductor device provided by the present embodiment. The semiconductor device is provided with a plurality of first ICs and a plurality of second ICs, and mobility of TFTs in the first ICs is greater than mobility of TFTs in the second ICs. The semiconductor device and the electronic device provided by the present embodiment can be applied to different devices such as control devices and display devices. Specifically, the devices may include any products or components having a driving function or a control function such as cell phones, computers, drivers, power mechanisms, or in-vehicle devices. Specific types of the devices are not limited here.

In summary, a semiconductor device, a sensor device, and an electronic device provided by the above embodiments of the present disclosure have been described in detail, which illustrate principles and implementations thereof. However, the description of the above embodiments is only for helping to understand the technical solution of the present disclosure and core ideas thereof, and it is understood by those skilled in the art that many changes and modifications to the described embodiment can be carried out without departing from the scope and the spirit of the disclosure that is intended to be limited only by the appended claims.

1. A semiconductor device, comprising:
an insulating substrate;
a first integrated circuit (IC) disposed on the insulating substrate and comprising a first thin-film transistor (TFT); and
a second IC disposed on the insulating substrate and comprising a second TFT;
wherein mobility of a charge carrier in an active layer of the first TFT is greater than mobility of a charge carrier in an active layer of the second TFT.

2. The semiconductor device of claim 1, wherein along a length direction of a channel area corresponding to the first TFT and the second TFT, an average size of a plurality of particles in the active layer of the first TFT is greater than an average size of a plurality of particles in the active layer of the second TFT.

3. The semiconductor device of claim 2, wherein the particles in the active layer of the first TFT comprise a first boundary along the first direction and a second boundary along the second direction; and
wherein the first direction is same as the length direction of the channel area, the second direction is perpendicular to the length direction of the channel area, and a length of the first boundary is greater than a length of the second boundary.

4. The semiconductor device of claim 2, wherein the active layer of the first TFT and the active layer of the second TFT have same material, the active layer of the first TFT and the active layer of the second TFT are disposed on a same layer, a gate of the first TFT and a gate of the second TFT are disposed on a same layer, and a source/drain metal layer of the first TFT and a source/drain metal layer of the second TFT are disposed on a same layer.

5. The semiconductor device of claim 2, wherein a gate of the first TFT is insulatedly disposed on the active layer of the first TFT, a source/drain metal layer of the first TFT is insulatedly disposed on the gate of the first TFT, the active layer of the second TFT is insulatedly disposed on the source/drain metal layer of the first TFT, and a gate of the second TFT is insulatedly disposed on the active layer of the second TFT.

6. The semiconductor device of claim 1, wherein the first TFT comprises a low-temperature polycrystalline silicon TFT, and the second TFT comprises a metal oxide TFT;
wherein the active layer of the first TFT is disposed on the insulating substrate, a gate of the first TFT is insulatedly disposed on the active layer of the first TFT, and a gate of the second TFT and the gate of the first TFT are disposed on a same layer.

7. The semiconductor device of claim 6, comprising a gate insulating layer disposed on the gate of the first TFT and the gate of the second TFT, wherein the active layer of the second TFT is disposed on the gate insulating layer, the source/drain metal layer of the first TFT and the source/drain metal layer of the second TFT are disposed on a same layer and are disposed on the gate insulating layer.

8. The semiconductor device of claim 6, wherein the source/drain metal layer of the second TFT is at least partly disposed on a surface of the active layer of the second TFT, and is electrically connected to the active layer of the second TFT.

9. The semiconductor device of claim 2, wherein a type of the first TFT and a type of the second TFT are different, the second TFT is disposed on the first TFT, and the semiconductor device comprises a passivation layer disposed between the first TFT and the second TFT.

10. The semiconductor device of claim 9, wherein the semiconductor device comprises a second gate insulating layer, a gate of the second TFT is disposed on the passivation layer, the second gate insulating layer is disposed on the passivation layer, the active layer of the second TFT is disposed on the second gate insulating layer, and the source/drain metal layer of the second TFT is disposed on the second gate insulating layer; and
wherein the source/drain metal layer of the second TFT is at least partly disposed on a surface of the active layer of the second TFT, and is electrically connected to the active layer of the second TFT.

11. The semiconductor device of claim 1, wherein the first IC comprises any one of a gate driving IC, a logic control IC, a low-pass control IC, or a digital-to-analog converter IC, and the second IC comprises any one of a memory IC or an operational amplifier IC.

12. A sensor device, comprising a sensor area and an outer circuit area defined on a side of the sensor area;
wherein the sensor device comprises:
an insulating substrate;
a sensor unit disposed on the insulating substrate corresponding to the sensor area; and
an integrated circuit (IC), wherein the IC is at least partly disposed on the insulating substrate corresponding to the outer circuit area, and is configured to control the sensor unit;
wherein the IC comprises:
a first IC disposed on the insulating substrate and comprising a first thin-film transistor (TFT); and
a second IC disposed on the insulating substrate and comprising a second TFT;
wherein mobility of a charge carrier in an active layer of the first TFT is greater than mobility of a charge carrier in an active layer of the second TFT.

13. The sensor device of claim 12, wherein in the sensor area, the sensor device comprises:
a plurality of gate signal lines; and
a plurality of data signal lines, wherein the data signal lines and the gate signal lines cross each other and form a plurality of intersection areas, each of the intersection areas is provided with at least one sensor unit, and the sensor unit comprises a first sensor module;
wherein the data signal lines are electrically connected to the first sensor module, and the data signal lines are electrically connected to the IC disposed in the outer circuit area.

14. The sensor device of claim 13, wherein the data signal lines are electrically connected to the first IC, the second IC is electrically connected to the first IC, and the first IC is electrically connected between the sensor unit and the second IC.

15. The sensor device of claim 14, wherein the first IC comprises any one of a low-pass control IC, an analog control IC, or a digital-to-analog converter IC, and the second IC comprises any one of a memory IC or an operational amplifier IC.

16. The sensor device of claim 14, wherein the first IC comprises a low-pass control IC electrically connected to the data signal lines, an analog control IC electrically connected to the low-pass control IC, and a digital-to-analog converter IC electrically connected to the analog control IC, the second IC comprises a memory IC, the low-pass control IC is electrically connected between the sensor unit and the analog control IC, and the digital-to-analog converter IC is electrically connected between the analog control IC and the memory IC.

17. The sensor device of claim 15, wherein the active layer of the first TFT comprises a low-temperature polycrystalline silicon, and the active layer of the second TFT comprises a metal oxide.

18. The sensor device of claim 14, wherein the first IC and the second IC are both disposed on a same side of the insulating substrate, the first sensor module is disposed on a side of the first IC away from the insulating substrate, and the first sensor module is electrically connected to the first TFT.

19. The sensor device of claim 14, wherein the first IC and the second IC are both disposed on a first surface of the insulating substrate, and the first sensor module is disposed on a second surface of the insulating substrate opposite to the first surface; and
wherein the first sensor module is electrically connected to the first TFT by a through-hole defined on the insulating substrate.

20. An electronic device, comprising a semiconductor device;
wherein the semiconductor device comprises:
an insulating substrate;
a first integrated circuit (IC) disposed on the insulating substrate and comprising a first thin-film transistor (TFT); and
a second IC disposed on the insulating substrate and comprising a second TFT; or
wherein the electronic device comprises a sensor device comprising a sensor area and an outer circuit area defined on a side of the sensor area;
wherein the sensor device comprises:
an insulating substrate;
a sensor unit disposed on the insulating substrate corresponding to a sensor area; and
an integrated circuit (IC), wherein the IC is at least partly disposed on the insulating substrate corresponding to the outer circuit area, and is configured to control the sensor unit;
wherein the IC comprises:
a first IC disposed on the insulating substrate and comprising a first thin-film transistor (TFT); and
a second IC disposed on the insulating substrate and comprising a second TFT;
wherein mobility of a charge carrier in an active layer of the first TFT is greater than mobility of a charge carrier in an active layer of the second TFT.
